(19) United States
(12) Patent Application Publication
(10) Pub. No.: US 2019/0036498 A1
(43) Pub. Date: Jan. 31, 2019

(54) BURST MODE TRANS-IMPEDANCE AMPLIFIER

(71) Applicant: Hangzhou Hongxin Microelectronics Technology Co., Ltd., Hangzhou (CN)

(72) Inventor: Hehong Zou, Hangzhou (CN)

(73) Assignee: Hangzhou Hongxin Microelectronics Technology Co., Ltd., Hangzhou (CN)

(21) Appl. No.: 15/844,543

(22) Filed: Dec. 16, 2017

(30) Foreign Application Priority Data
Jul. 25, 2017 (CN) 201710612188.9

(51) Int. Cl. H03F 3/08; H03G 1/00

(52) U.S. Cl. CPC H03F 3/08; H03G 1/0047

(57) ABSTRACT

The present invention provides a burst mode trans-impedance amplifier, comprising: a voltage input circuit, used for sensing an optical signal and converting the optical signal into an input voltage signal; a differential circuit, having two input ends and an output end, wherein one input end is coupled to the voltage input circuit and is used for receiving the input voltage signal, the other input end is coupled to a threshold voltage signal, and the output end is used for regulating and outputting a differential voltage signal according to the input voltage signal and the threshold voltage signal; and a feedback regulation circuit, having an input end and an output end, wherein the input end is coupled to the output end of the differential circuit and is used for receiving the differential voltage signal, and the output end is coupled to the voltage input circuit.

### CROSS-REFERENCE TO RELATED APPLICATIONS

This Non-provisional application claims priority under 35 U.S.C. § 119(a) on Patent Application No(s). 201710612188.9 filed in China on Jul. 25, 2017, the entire contents of which are hereby incorporated by reference.

### BACKGROUND OF THE INVENTION

### Field of the Invention

The present disclosure relates to the field of amplifier technology and, more particularly, to a burst mode trans-impedance amplifier.

### Description of the Related Art

In the prior art, an amplifier structure generally includes a photodiode, a trans-impedance amplifier, a single-ended differential amplifier, a complementary amplifier, and two integral control circuits. The photodiode converts an optical signal into a current signal, and then the current signal is converted into a voltage signal by the trans-impedance amplifier. An input end and an output end of the trans-impedance amplifier are coupled to two input ends of one of the two integral control circuits. An output end of the integral control circuit is coupled to a current source. One end of the current source is coupled to the input end of the trans-impedance amplifier, and the other end is grounded. Therefore, the integral control circuit and the current source form a first DC circuit. The first DC circuit is used for regulating an output signal of the trans-impedance amplifier according to input and output signal of the trans-impedance amplifier. An output end of the single-ended differential amplifier is coupled to an output end of the trans-impedance amplifier, an output end of the single-ended differential amplifier is coupled to an input end of the complementary amplifier. An output end of the complementary amplifier is used for outputting an output voltage and is coupled to an input end of the other integral control circuit, and the output end of this integral control circuit is coupled to the other input end of the single-ended differential amplifier. The single-ended differential amplifier, the complementary amplifier and this integral control circuit form a second DC circuit. The second DC circuit is used for regulating an output signal of the complementary amplifier according to input of the single-ended differential amplifier and output of the complementary amplifier. Therefore, the amplifier is regulated by the first DC circuit and the second DC circuit to output an output signal so as to meet a DC operating point. However, in a burst mode, using a dynamic regulation output manner by means of the first DC circuit and the second DC circuit is too long in response time for the amplifier.

### BRIEF SUMMARY OF THE INVENTION

The present disclosure provides a burst mode trans-impedance amplifier to solve the above problems.

To solve the above problems, an embodiment of the present disclosure provides a burst mode trans-impedance amplifier, including:

a voltage input circuit, sensing an optical signal and converting the optical signal into an input voltage signal;

a differential circuit, having two input ends and an output end, wherein one input end is coupled to the voltage input circuit and is used for receiving the input voltage signal, the other input end is coupled to a threshold voltage signal, and the output end is used for regulating and outputting a differential voltage signal according to the input voltage signal and the threshold voltage signal; and
a feedback regulation circuit, having an input end and an output end, the input end being coupled to the output end of the differential circuit and used for receiving the differential voltage signal, the output end being coupled to the voltage input circuit and used for outputting a voltage regulation signal to the voltage input circuit according to the differential voltage signal.

As an embodiment, the voltage input circuit may include:

an optical diode, which may be used for receiving the optical signal and converting the optical signal into a voltage signal;

an amplifier, which may have an input end and an output end, wherein the input end may be coupled to the optical diode and may be used for receiving the voltage signal outputted by the optical diode, and the output end may be used for outputting the input voltage signal; and

a feedback resistor, which may be coupled to the input end and the output end of the amplifier.

As an embodiment, the secondary amplifier unit may include:

a differential amplifier, which may have two input ends and an output end, wherein one input end may be coupled to the output end of the voltage input circuit and may be used for receiving the input voltage signal, the other input end may be coupled to a threshold voltage signal, and the output end may be used for outputting a differential voltage signal; and

a complementary amplifier, which may be coupled to the differential amplifier and may be used for eliminating crossover distortion of the differential voltage signal outputted by the differential amplifier and then outputting the differential voltage signal with crossover distortion eliminated.

As an embodiment, the feedback regulation circuit may include:

an integral control circuit, which may have an input end and an output end, wherein the input end may be coupled to the output end of the differential circuit and may be used for receiving the differential voltage signal, and the output end may be used for outputting an integral voltage signal according to the differential voltage signal; and

a current source, which may be coupled to the integral control circuit and the voltage input circuit and may be used for receiving and outputting, according to the integral voltage signal, the voltage regulation signal.

As an embodiment, generating the threshold voltage signal may use a dummy TIA.

Compared with the prior art, beneficial effects of the present disclosure are as below. In a burst mode of the burst mode trans-impedance amplifier of the present disclosure, the output signal is regulated only by means of one DC circuit, which is fast in response time. The number of adopted integrators is changed from originally two to one because the number of the DC circuits used for regulating the DC operating point is changed to one. Furthermore, to ensure the gain and bandwidth of the amplifier, resistors in the integral control circuit generally are MΩ-level resistors, and capacitors are capacitors of a tens of PF. Therefore, the resistors and the capacitors in the integral control circuit account for more than 10% of the whole amplifier. However, compared with an amplifier in the prior art, the burst mode trans-impedance amplifier of the present disclosure may reduce the number of the resistors and the capacitors in the integral control circuit, which may reduce, to a great extent, the volume of the burst mode trans-impedance amplifier.

### BRIEF DESCRIPTION OF THE DRAWINGS

FIG. 1 is a circuit diagram of a burst mode trans-impedance amplifier according to the present disclosure; and

FIG. 2 is a circuit diagram of a dummy TIA of the burst mode trans-impedance amplifier according to the present disclosure.

Reference numerals: 1 voltage input circuit; 2 differential circuit; 3 feedback regulation circuit; 100 optical diode; 200 trans-impedance amplifier; 300 differential amplifier; 400 complementary amplifier; 500 integral control circuit; and 600 current source.

### DETAILED DESCRIPTION OF THE INVENTION

The foregoing and additional technical features and advantages of the present disclosure are described clearly and completely below, in conjunction with the accompanying drawings. Apparently, the described embodiments are some but not all of the embodiments of the present disclosure.

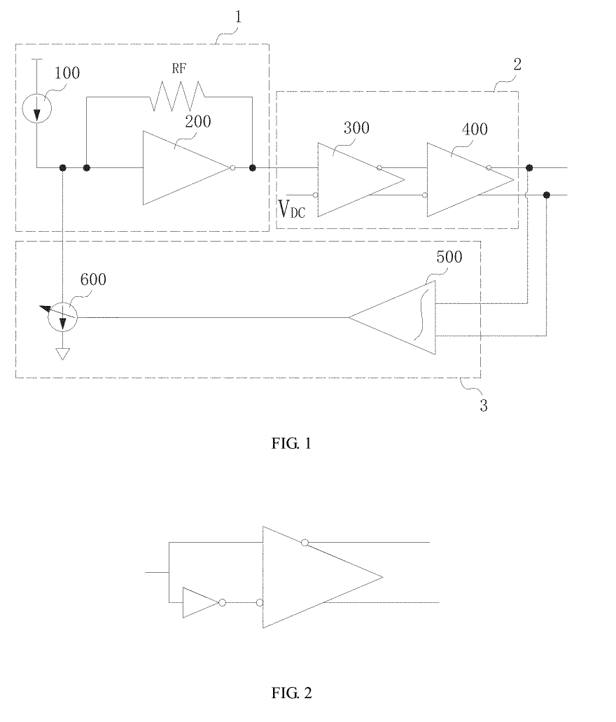

As shown in FIG. 1, a burst mode trans-impedance amplifier 200 includes a voltage input circuit 1, a differential circuit 2, and a feedback regulation circuit 3. The voltage input circuit 1 is used for sensing an optical signal and converting the optical signal into an input voltage signal. The differential circuit 2 has two input ends and an output end, wherein one input end is coupled to the voltage input circuit 1 and is used for receiving the input voltage signal, the other input end is coupled to a threshold voltage signal V_{DC}, and the output end is used for regulating and outputting a differential voltage signal according to the input voltage signal and the threshold voltage signal V_{DC}. The feedback regulation circuit 3 has an input end and an output end. The input end is coupled to the output end of the differential circuit 2 and is used for receiving the differential voltage signal, and the output end is coupled to the voltage input circuit 1 and is used for outputting a voltage regulation signal to the voltage input circuit 1 according to the differential voltage signal. In this way, a DC operating point of the burst mode trans-impedance amplifier 200 is regulated so that the differential circuit 2 outputs a differential voltage signal meeting the DC operating point.

The voltage input circuit 1 includes an optical diode 100, an amplifier and a feedback resistor. The optical diode 100 is used for receiving the optical signal and converting the optical signal into a voltage signal. The amplifier is used for outputting an input voltage signal according to the above voltage signal amplified. The amplifier has an input end and an output end. The input end is coupled to the optical diode 100 and is used for receiving the voltage signal, and the output end is used for outputting the input voltage signal. The feedback resistor is coupled to the input end and the output end of the amplifier.

The differential circuit 2 includes a differential amplifier 300 and a complementary amplifier 400. The differential amplifier 300 has two input ends and an output end, wherein one input end is coupled to the output end of the voltage input circuit 1 and is used for receiving the input voltage signal, the other input end is coupled to the threshold voltage signal V_{DC}, and the output end is used for outputting the differential voltage signal. The complementary amplifier 400 is coupled to the differential amplifier 300 and is used for eliminating crossover distortion of the differential voltage signal outputted by the differential amplifier 300 and then outputting the differential voltage signal with crossover distortion eliminated.

The feedback regulation circuit 3 includes an integral control circuit 500 and a current source 600. The integral control circuit 500 has an input end and an output end. The input end is coupled to the output end of the differential circuit 2 and is used for receiving the differential voltage signal. The output end is used for outputting an integral voltage signal according to the differential voltage signal. The current source 600 is coupled to the integral control circuit 500 and the voltage input circuit 1 and is used for receiving and outputting, according to the integral voltage signal, the voltage regulation signal.

As shown in FIG. 2, in another embodiment, the above threshold voltage signal V_{DC} is generated using a dummy trans-impedance amplifier (TIA).

In a burst mode of the burst mode amplifier of the present disclosure, the output signal is regulated only by means of one DC circuit, which is fast in response time. The number of adopted integrators is changed from originally two to one because the number of the DC circuits used for regulating the DC operating point is changed to one. Furthermore, to ensure the gain and bandwidth of the amplifier, resistors in the integral control circuit 500 generally are MΩ-level resistors, and capacitors are capacitors of a tens of PF. Therefore, the resistors and the capacitors in the integral control circuit 500 account for more than 10% of the whole amplifier. However, compared with an amplifier in the prior art, the burst mode amplifier of the present disclosure may reduce the number of the resistors and the capacitors in the integral control circuit 500, which may reduce, to a great extent, the volume of the burst mode amplifier.

In the above specific embodiments, the objectives, the technical solutions and the beneficial effects of the present disclosure are further described in detail. However, it should be understood that the above embodiments are merely specific embodiments of the present disclosure and are not intended to limit the scope of protection of the present disclosure. It is particularly pointed out that for those skilled in the art, all modifications, equivalent substitutions and improvements made within the spirit and principle of the present disclosure shall fall within the scope of protection of the present disclosure.

What is claimed is:

1. A burst mode trans-impedance amplifier, comprising:
a voltage input circuit, sensing an optical signal and converting the optical signal into an input voltage signal;
a differential circuit, having two input ends and an output end, wherein one input end is coupled to the voltage input circuit and is used for receiving the input voltage signal, the other input end is coupled to a threshold voltage signal, and the output end is used for regulating and outputting a differential voltage signal according to the input voltage signal and the threshold voltage signal; and
a feedback regulation circuit, having an input end and an output end, the input end being coupled to the output end of the differential circuit and used for receiving the differential voltage signal, the output end being coupled to the voltage input circuit and used for outputting a voltage regulation signal to the voltage input circuit according to the differential voltage signal.

2. The burst mode trans-impedance amplifier according to claim 1, wherein the voltage input circuit comprises:
an optical diode, used for receiving the optical signal and converting the optical signal into a voltage signal;
an amplifier, having an input end and an output end, the input end being coupled to the optical diode and used for receiving the voltage signal outputted by the optical diode, and the output end being used for outputting the input voltage signal; and
a feedback resistor, coupled to the input end and the output end of the amplifier.

3. The burst mode trans-impedance amplifier according to claim 1, wherein the differential circuit comprises:
a differential amplifier, having two input ends and an output end, wherein one input end is coupled to the output end of the voltage input circuit and is used for receiving the input voltage signal, the other input end is coupled to a threshold voltage signal, and the output end is used for outputting a differential voltage signal; and
a complementary amplifier, coupled to the differential amplifier and used for eliminating crossover distortion of the differential voltage signal outputted by the differential amplifier and then outputting the differential voltage signal with crossover distortion eliminated.

4. The burst mode trans-impedance amplifier according to claim 1, wherein the feedback regulation circuit comprises:
an integral control circuit, having an input end and an output end, the input end being coupled to the output end of the differential circuit and used for receiving the differential voltage signal, and the output end being used for outputting an integral voltage signal according to the differential voltage signal; and
a current source, coupled to the integral control circuit and the voltage input circuit and used for receiving and outputting, according to the integral voltage signal, the voltage regulation signal.

5. The burst mode trans-impedance amplifier according to claim 1, wherein generating the threshold voltage signal uses a dummy TIA.
